(19) United States
(12) Patent Application Publication
(10) Pub. No.: US 2014/0076753 A1
(43) Pub. Date: Mar. 20, 2014

(54) Case for wireless devices

(71) Applicants: Jamie Limber, Tempe, AZ (US); William D. Hinz, II, Fort Collins, CO (US); Jay C. Cronin, Fort Collins, CO (US)

(72) Inventors: Jamie Limber, Tempe, AZ (US); William D. Hinz, II, Fort Collins, CO (US); Jay C. Cronin, Fort Collins, CO (US)

(21) Appl. No.: 13/573,476

(22) Filed: Sep. 17, 2012

(51) Int. Cl. H05K 7/00; B65B 5/04; H04M 1/02

(52) U.S. Cl. 206/320; 53/461

(57) ABSTRACT

A device for protecting wireless communication devices having a two piece cover, a front cover and a rear cover. The front cover has a shaped body with a front cover lip; the rear cover has a shaped rear body with a rear cover lip. Each front and rear cover have sides that have a curved shape. Each front and rear cover have tops and bottoms that have a curved shape. The device further has at least one tab located on an edge of the front cover lip and at least one complementary tab detent located in the edge of the rear cover lip. The device further has at least one tab located on an edge of the rear cover lip and at least one complementary tab detent located in the edge of the front cover lip. The device further includes bumpers attached to at least one corner of the device.

### FIELD OF THE INVENTION

The present invention relates to a device and method for a cell phone jacket designed to cover, and wireless devices, such as, but not limited to, cellular phones.

### BACKGROUND OF INVENTION

Wireless communications devices are a ubiquitous feature in today's culture. They are constantly in use. However, a downside of the near continuous use is breakage. It is not unknown for wireless communications devices to be dropped or to fall off of tables, counters or the like.

The common solution to this breakage problem is to cover the wireless communications devices with a cover or second skin. Frequently these covers are made of a hard stiff plastic, which, while preventing corners of the wireless communications device from chipping, do little to abate damage to screens and interior electronics. This is because a hard, stiff plastic merely transmits any force of impact directly through the case and into the wireless communications device.

There are also very soft, rubber-like, cases. These are designed to cushion an impact force. However, while these cases absorb a portion of the impact force, the rest of the impact force is transmitted directly through the case and into the wireless communications device.

The present invention and method provides a solution to the above problems by providing a case for wireless communications devices that redistributes impact force into energy wells, thereby greatly reducing or eliminating any harmful transmission of impact force into the interior of the wireless communications device.

### SUMMARY OF THE INVENTION

It is an object of the present invention to provide a case for wireless communications devices that redistributes impact force into energy wells, thereby greatly reducing or eliminating any harmful transmission of impact force into the interior of the wireless communications device.

The novel features that are considered characteristic of the invention are set forth with particularity in the appended claims. The invention itself, however, both as to its structure and its operation together with the additional object and advantages thereof will best be understood from the following description of the preferred embodiment of the present invention when read in conjunction with the accompanying drawings. Unless specifically noted, it is intended that the words and phrases in the specification and claims be given the ordinary and accustomed meaning to those of ordinary skill in the applicable art or arts. If any other meaning is intended, the specification will specifically state that a special meaning is being applied to a word or phrase. Likewise, the use of the words “function” or “means” in the Description of Preferred Embodiments is not intended to indicate a desire to invoke the special provision of 35 U.S.C. §112, paragraph 6 to define the invention. To the contrary, if the provisions of 35 U.S.C. §112, paragraph 6, are sought to be invoked to define the invention(s), the claims will specifically state the phrases “means for” or “step for” and a function, without also reciting in such phrases any structure, material, or act in support of the function. Even when the claims recite a “means for” or “step for” performing a function, if they also recite any structure, material or acts in support of that means of step, then the intention is not to invoke the provisions of 35 U.S.C. §112, paragraph 6. Moreover, even if the provisions of 35 U.S.C. §112, paragraph 6, are invoked to define the inventions, it is intended that the inventions not be limited only to the specific structure, material or acts that are described in the preferred embodiments, but in addition, include any and all structures, materials or acts that perform the claimed function, along with any and all known or later-developed equivalent structures, materials or acts for performing the claimed function.

### BRIEF DESCRIPTION OF THE DRAWINGS

The invention will be more fully understood by referring to the following Detailed Description of Specific Embodiments in conjunction with the Drawings, of which:

FIG. 1 is a perspective view of the present invention;

FIG. 2 is a front view of the present invention;

FIG. 3 is a bottom view of the present invention;

FIG. 4 is a top view of the present invention;

FIG. 5 is a first side view of the present invention;

FIG. 6 is a second side view of the present invention;

FIG. 7 is a rear view of the present invention;

FIG. 8 is an exploded view of the present invention;

FIG. 9 is close up of a corner of the present invention;

FIG. 10 is an exploded view of the a corner of the present invention (showing the button removed);

FIG. 11 is a cut-away view of a corner of the present invention;

FIG. 12 is a cut-away exploded view of a corner of the present invention;

FIG. 13 is an exploded view of a corner of the present invention illustrating insertion/removal of a wireless devise;

FIG. 14 is an exploded view of the present invention illustrating insertion/removal of a wireless devise;

FIG. 15 illustrates a wireless device, which is protected by the present invention, being dropped;

FIG. 16 is a side view of the present invention prior to the device, with phone, being dropped; and

FIG. 17 is a side view of the present invention after the device, with phone, has been dropped.

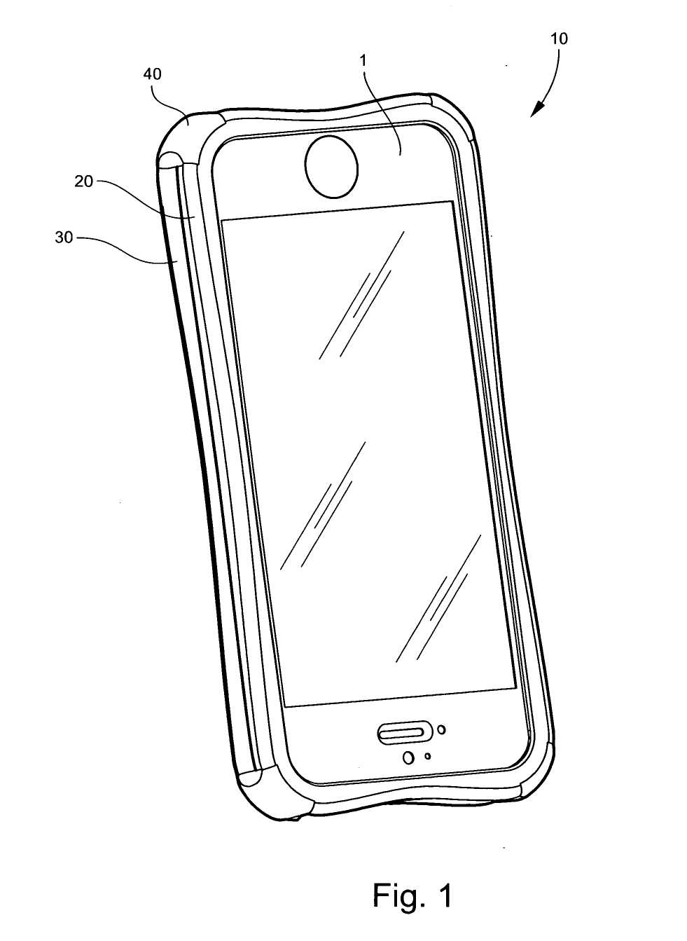

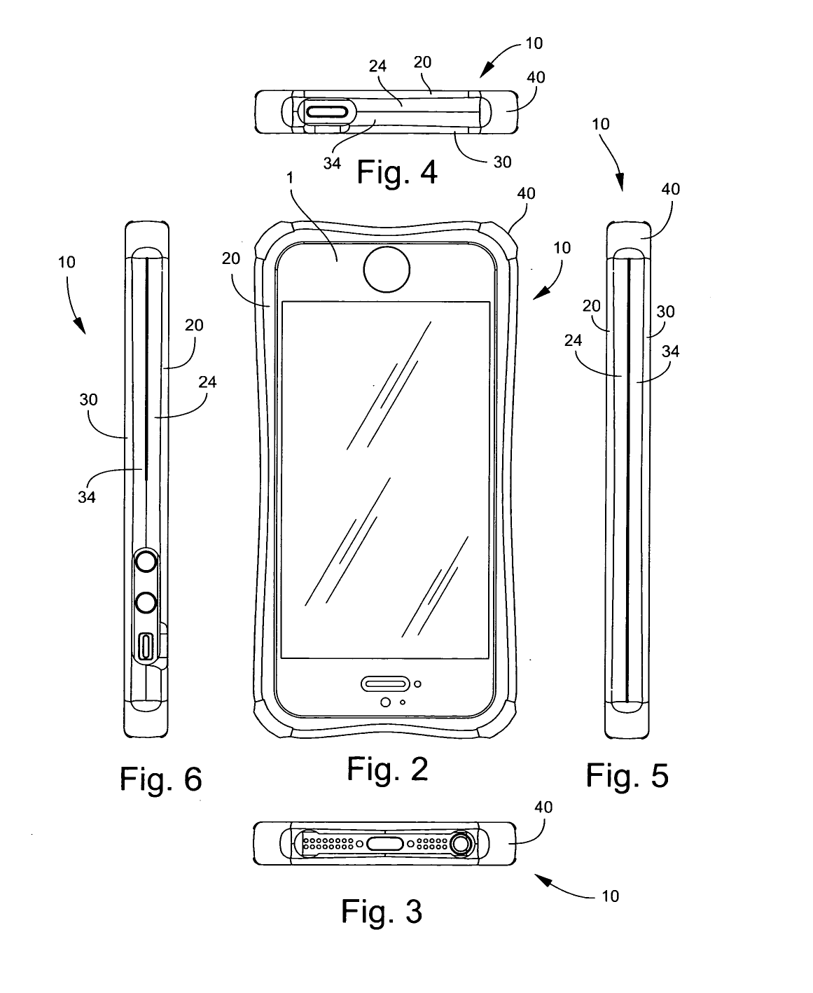

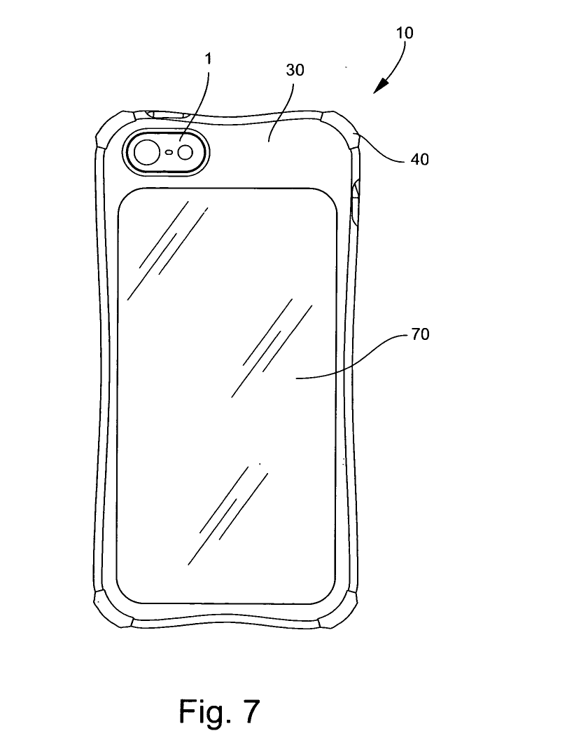

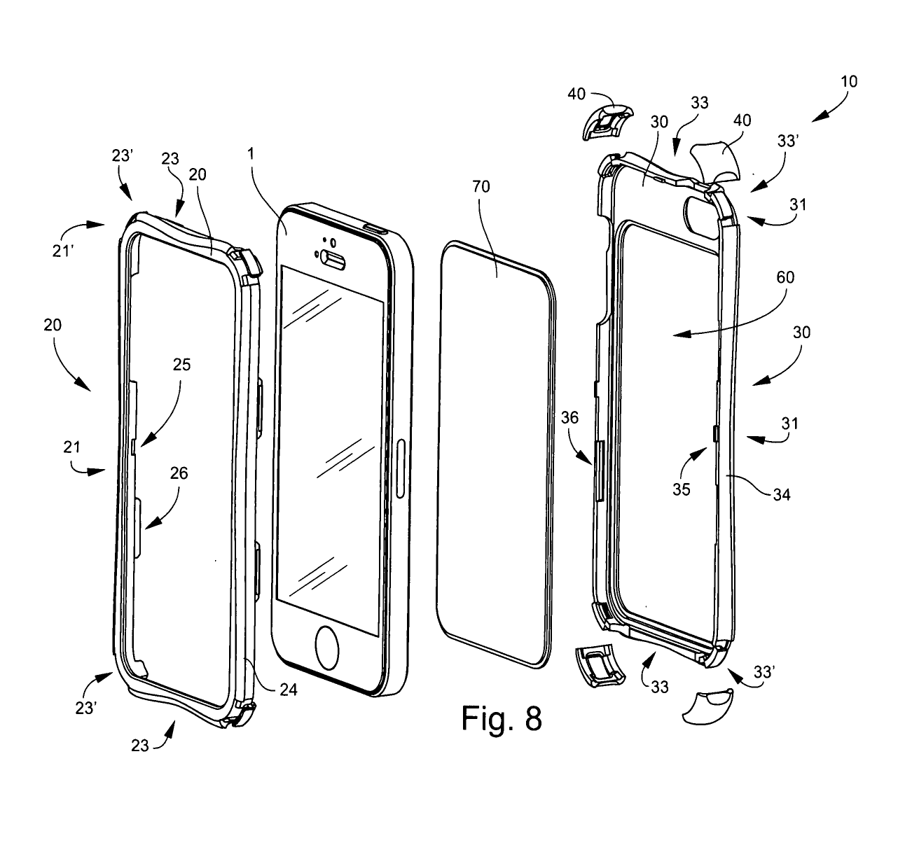

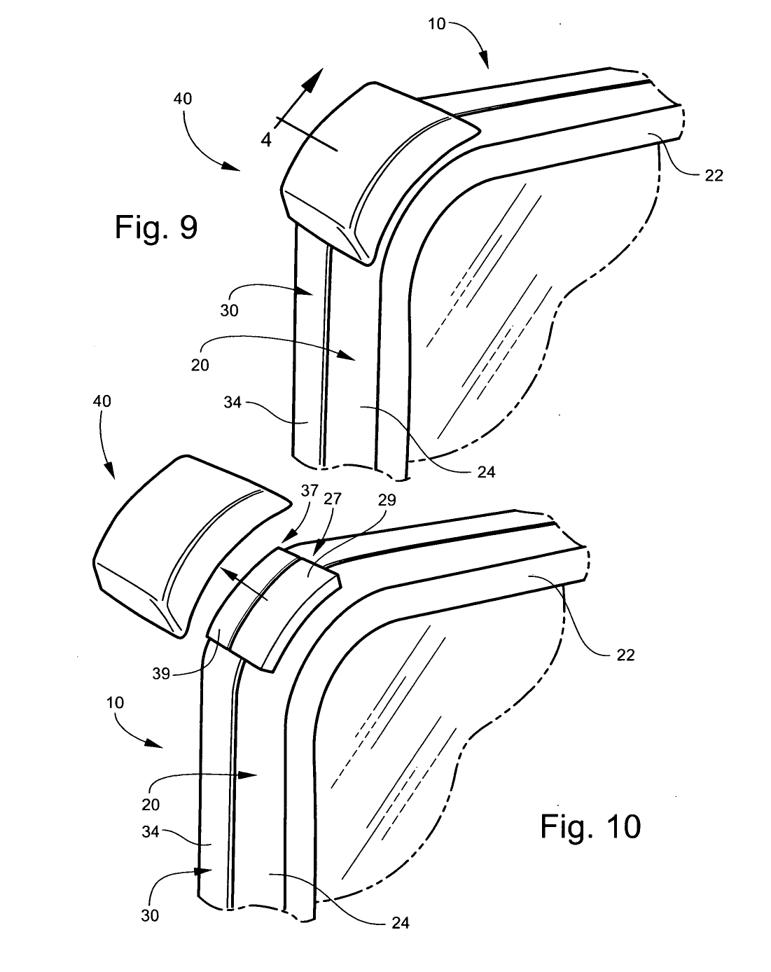

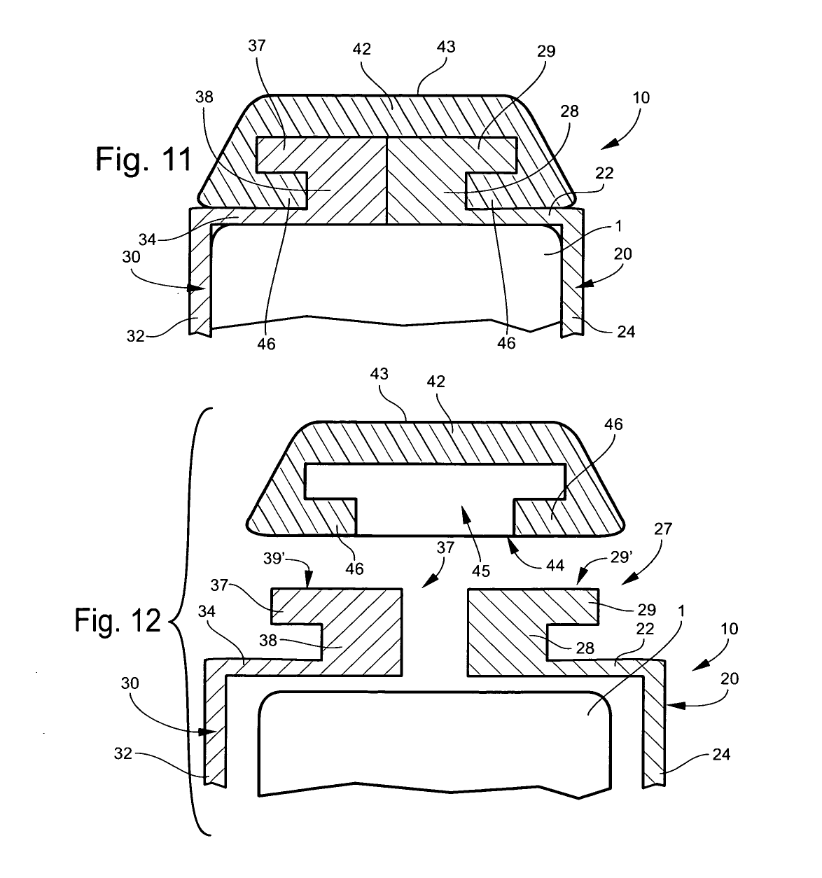

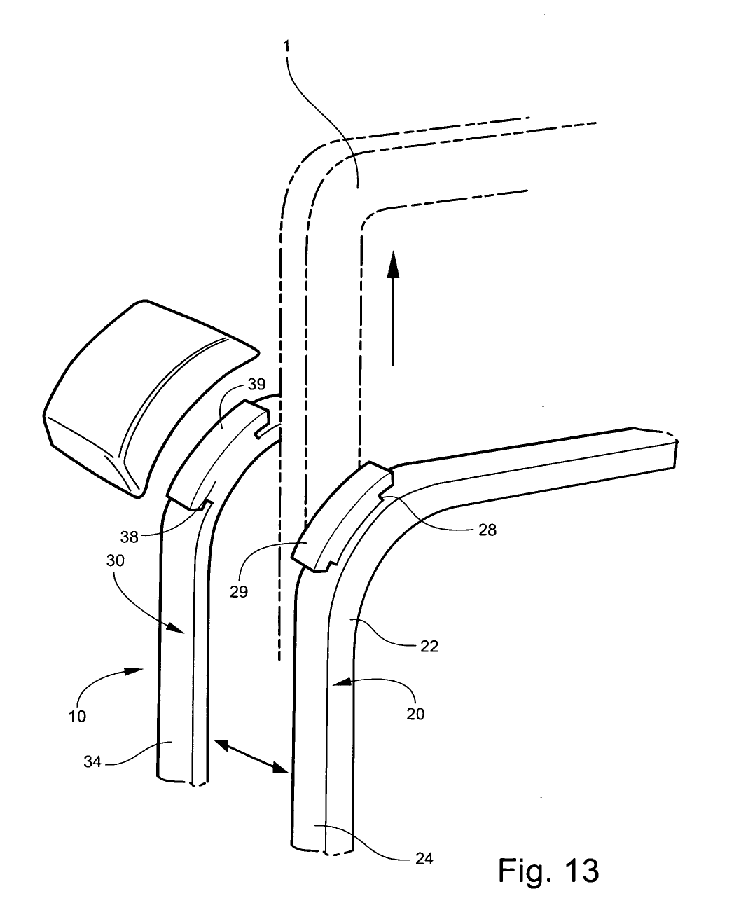

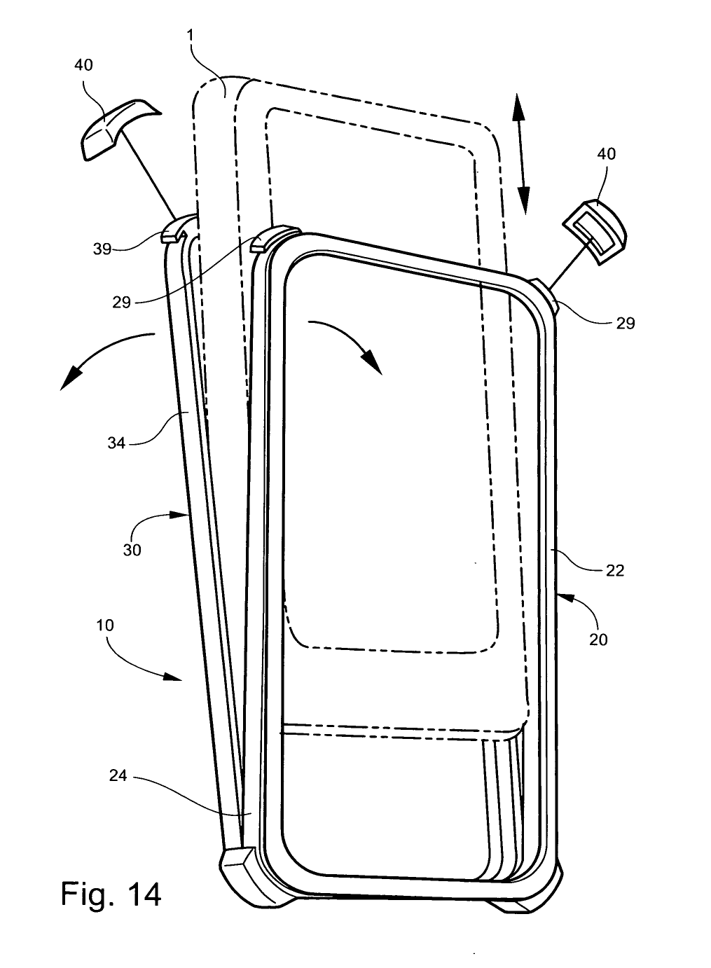

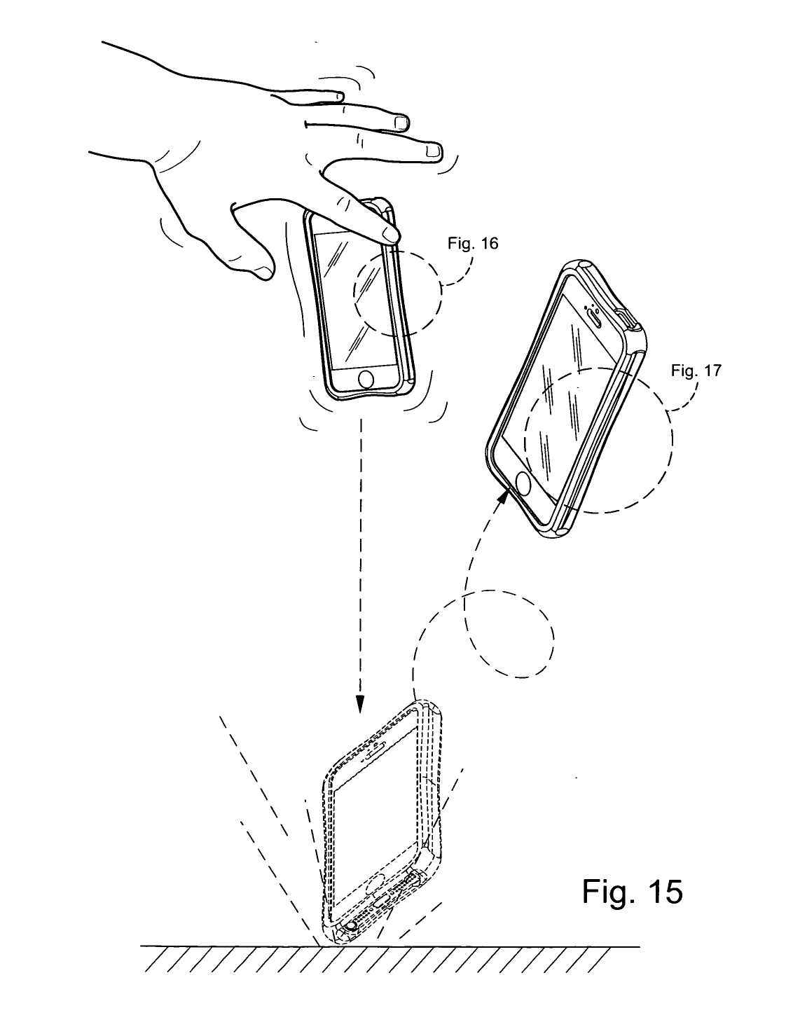

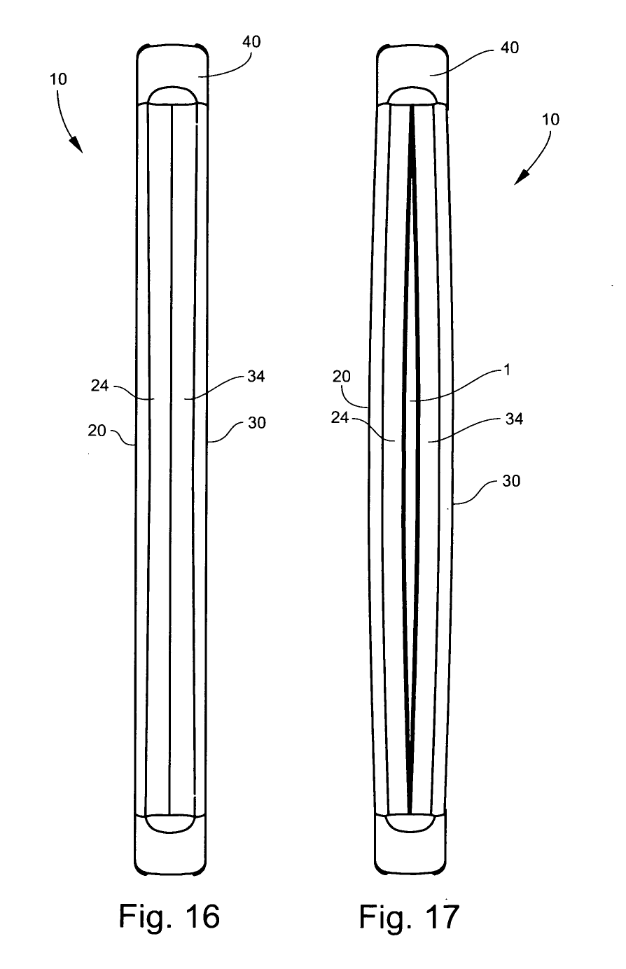

### DETAILED DESCRIPTION OF SPECIFIC EMBODIMENTS

The present invention is a case or protective jacket 10 for wireless communications devices 1 that redistributes impact force into energy wells, thereby greatly reducing or eliminating any harmful transmission of impact force into the interior of the wireless communications device.

The preferred protective jacket 10 comprises at least two pieces of a protective, semi-rigid skeleton that surrounds the perimeter edges of the wireless device 1. In a preferred embodiment there is a front cover 20 and a rear cover 30. The front and rear covers, 20 and 30, are adapted to snugly fit a prespecified wireless communications device 1.

The preferred front cover 20 comprises a shaped front body 22 having a front cover lip 24 that is sized to fit around the periphery of the prespecified wireless communications device 1. Preferably the front cover 20 has a width mid-point dimension 21 that is less than the width top and bottom dimension 21′. Further, the front cover 20 has a height mid-point dimension 23 that is less than the side height dimension 23′. Thus, the sides, top and bottom of the front cover 20 have a bowed or curved shape similar to a leaf spring. This bowed or curved shape is effectively an energy well.

The preferred rear cover 30 comprises a shaped rear body 32 having a rear cover lip 34 that is sized to fit around the periphery of the prespecified wireless communications device 1. Preferably the rear cover 30 has a width mid-point dimension 31 that is less than the width top and bottom dimension 31′. Further, the rear cover 30 has a height mid-point dimension 33 that is less than the side height dimension 33′. Thus, the sides, top and bottom of the rear cover 30 have a bowed or curved shape similar to a leaf spring. This bowed or curved shape is effectively an energy well.

Preferably, the front cover lip 24 and the rear cover lip 34, when the front cover 20 and rear cover 30 are attached to the wireless communications device 1, are located in close proximity to each other.

Moreover, the front cover lip 24 includes at least front cover one tab detent 25 located on an inner surface of the front cover lip 24. Preferably there are at least two front cover tab detents 25, one located on each side, and more preferably there are at least three front cover tab detents 25, one located on each side and one located on the top portion of the front cover lip 24. Further, the rear cover lip 34 includes at least one rear cover tab 35 located on an edge of the rear cover lip 35. Preferably there are at least two rear cover tabs 35, one located on each side, and more preferably there are at least three rear cover tabs 35, one located on each side and one located on the top portion of the rear cover lip 34. Preferably the rear cover tabs 35 line up with and are receivable by the front cover tab detents 25. Most preferably, when the rear cover tabs 35 are receive by the front cover tab detents 25, a small amount of force is required to seat the rear cover tabs 35 into the front cover tab detents 25. This force slightly expands the front cover mid-point width dimension and allows for a frictive engagement between the rear cover tabs 35 and the front cover tab detents 25.

It is considered to fall within the scope of the present invention that there may be at least one front cover tabs 26 located on an edge of the front cover lip 24 and at least one rear cover tab detents 36 located in an inner surface of the rear cover lip 34. As above, when the front cover tabs 26 are receive by the rear cover tab detents 36, a small amount of force is required to seat the front cover tabs 26 into the rear cover tab detents 36. This force slightly expands the front cover mid-point width dimension 21 and allows for a frictive engagement between the front cover tabs 26 and the rear cover tab detents 36.

Located at at least one corner, preferably each corner, of the front cover 20, essentially adjacent to the front cover lip 24, is at least one elevated front cover button 27, comprising a stem 28 and a head 29. The head 29 of each button 27 is sized such that it is larger than the stem 28 thereby creating an overhanging edge 29′ on at least one side of the button 27. In a preferred embodiment, the overhanging edge 29′ is on three sides of the button 27, but other embodiment having two sides or four sides are also considered to fall within the scope of the present invention. Also in a preferred embodiment, each button 27 is generally rectangular in shape, but other shapes, such as square, circular, triangular and the like are considered to fall within the scope of the present invention. Finally, in a preferred embodiment, each of the at least one buttons 27 have the same shape as the other buttons 27, but individually different shapes may be used and still fall within the scope of the present invention.

Located at at least one corner, preferably each corner, of the rear cover 30, essentially adjacent to the rear cover lip 34, is at least one elevated rear cover button 37, comprising a stem 38 and a head 39. The head 39 of each button 37 is sized such that it is larger than the stem 38 thereby creating an overhanging edge 39′ on at least one side of the button 37. In a preferred embodiment, the overhanging edge 30′ is on three sides of the button 37, but other embodiment having two sides or four sides are also considered to fall within the scope of the present invention. Also in a preferred embodiment, each button 37 generally rectangular in shape, but other shapes, such as square, circular, triangular and the like are considered to fall within the scope of the present invention. Finally, in a preferred embodiment, each of the at least one buttons 37 have the same shape as the other buttons 37, but individually different shapes may be used and still fall within the scope of the present invention.

Further, there is at least one generally flexible bumper 40 that is sized to fit over aligned front and rear cover buttons 27 and 37. Each of the at least one generally flexible bumper 40 comprises a bumper body 42 with a front side 43 and a rear side 44. The rear side 44 includes a button shaped socket 45. The inside surface of the socket 45 is adapted to snugly fit the aligned front and rear cover buttons 27 and 37. Thus, there is a ledge 46 that mates with the overhanging edges 29′ and 39′.

Preferred embodiments of the jacket 10 include a series of openings, coverings or covered openings that allow a user to access and manipulate buttons or ports located around the perimeter edge of the wireless communication device 1 while still providing a protective continuous structure around the perimeter edge of the wireless communication device 1.

In an alternate embodiment, the present invention is contains a separate section or card 70 that is removable from the jacket 10. In this embodiment, the rear cover 30 includes an aperture 60 that is sized to fit, but snugly hold the card 70 in place when the card 70 is in the jacket 10. Thus, the card may be of any suitable shape as long as it can be held in place by the jacket and a portion of the card 70 displayed through the aperture 60.

In use, a user fits the front cover 20 over the front of a wireless communication device 1. The user then fits the rear cover 30 over the rear of the wireless communications device 1. (Steps 1 and 2 may be reversed). The user aligns the front and rear covers 20 and 30 until the front cover buttons 27 are located next to the rear cover buttons 37. Over at least one set of front and rear cover buttons 27 and 37 the user then places a bumper 40, forcing the bumper 40 over the front and rear cover buttons 27 and 37 until the bumper ledge 46 engages the front and rear cover overhanging edges 29′ and 39′, thereby securing the front and rear covers 20 and 30 around the wireless communications device 1. Removal of the protective cover 10 is just of a reverse of the above steps.

In a preferred embodiment, the generally flexible bumpers 40 are sufficiently yieldable such that when two are attached at adjacent corners, the front and rear cases 20 and 30 may be opened up enough to allow removal of the wireless communications device 1 without resort to removing the two adjacent flexible bumpers 40.

In protective use, when a wireless device 1 that is encased by the present invention 10 is dropped or fall from a height, typically a corner of the jacket 10 of the present invention is the first point of contact with the floor or ground. This is a result of the front and rear cover mid-point width and height dimensions, 21, 31, 23 and 33, being smaller than the front and rear cover width and height dimensions at the top, bottom and sides, 21′, 31′, 23′ and 33′.

Since the corners of the preferred jacket 10 has flexible bumpers 40 holding the front and rear covers 20 and 30 together, the bumper 40 will absorb a small portion of the impact force.

The remainder of the impact force is redirected along the perimeter of the front and rear covers 20 and 30 with a portion of the impact force used to overcome the frictive force at the various tabs and detents in the front and rear cover. Moreover, a portion of the impact force is redirected to flexing the bowed or curved shape of the sides, tops and bottoms of the front and rear covers 20 and 30. This effectively absorbs and redirects an amount of the impact force of the drop or fall, thereby preventing unwanted damage to the contained wireless device 1.

The preferred embodiment of the invention is described above in the Drawings and Description of Preferred Embodiments. While these descriptions directly describe the above embodiments, it is understood that those skilled in the art may conceive modifications and/or variations to the specific embodiments shown and described herein. Any such modifications or variations that fall within the purview of this description are intended to be included therein as well. Unless specifically noted, it is the intention of the inventor that the words and phrases in the specification and claims be given the ordinary and accustomed meanings to those of ordinary skill in the applicable art(s). The foregoing description of a preferred embodiment and best mode of the invention known to the applicant at the time of filing the application has been presented and is intended for the purposes of illustration and description. It is not intended to be exhaustive or to limit the invention to the precise form disclosed, and many modifications and variations are possible in the light of the above teachings. The embodiment was chosen and described in order to best explain the principles of the invention and its practical application and to enable others skilled in the art to best utilize the invention in various embodiments and with various modifications as are suited to the particular use contemplated.

What is claimed is:

1. A device for protecting wireless communication devices comprising:
a. a two piece cover, having a front cover and a rear cover,
i. the front cover having a shaped body with a front cover lip;
ii. the rear cover having a shaped rear body with a rear cover lip;
b. wherein each front and rear cover have sides that have a curved shape.

2. The device according to claim 1 wherein the front and rear cover have tops and bottoms that have a curved shape.

3. The device according to claim 1 further comprising at least one tab located on an edge of the front cover lip and at least one complementary tab detent located in the edge of the rear cover lip.

4. The device according to claim 1 further comprising at least one tab located on an edge of the rear cover lip and at least one complementary tab detent located in the edge of the front cover lip.

5. The device according to claim 4 further comprising at least one tab located on an edge of the rear cover lip and at least one complementary tab detent located in the edge of the front cover lip.

6. The device according to claim 1 further comprising bumpers attached to at least one corner of the device.

7. The device according to claim 2 further comprising bumpers attached to at least one corner of the device.

8. The device according to claim 3 further comprising bumpers attached to at least one corner of the device.

9. The device according to claim 4 further comprising bumpers attached to at least one corner of the device.

10. The device according to claim 5 further comprising bumpers attached to at least one corner of the device.

11. A method for protecting a wireless device comprising the steps of:
a. Providing a wireless device;
b. Providing a two piece jacket that covers that wireless device, each of said two pieces of the jacket having at least one energy well located in each piece; and
c. Placing the wireless device within the two piece jacket; wherein the two piece jacket is capable of redirecting impact from any corner to energy wells located in the two pieces of the jacket.

12. The method according to claim 11 further comprising the step of holding the two pieces of the jacket together using at least one flexible bumper attached to at least one corner of the jacket.
